(19) United States
(12) Patent Application Publication
(10) Pub. No.: US 2008/0052609 A1
(43) Pub. Date: Feb. 28, 2008

(54) Method and apparatus to perform erasure forecasting in communication systems

(76) Inventors: Chia-Ning Peng, Fremont, CA (US); Po Tong, Los Altos, CA (US); Cory Samuel Modlin, Chevy Chase, MD (US); Peter James Melsa, Niles, MI (US)

Correspondence Address: TEXAS INSTRUMENTS INCORPORATED, P O BOX 655474, M/S 3999, DALLAS, TX, 75265, US

(21) Appl. No.: 11/503,815

(22) Filed: Aug. 14, 2006

(51) Int. Cl. H04L 1/00; G08C 25/00; G06F 11/00; H03M 13/00

(52) U.S. Cl. 714/799

(57) ABSTRACT

Methods and apparatus to perform erasure forecasting in communication systems are disclosed. A disclosed example apparatus comprises a forward error correction (FEC) decoder to decode a first codeword and to provide a first error indication for the first codeword, an erasure forecaster to make an erasure decision for a second codeword based on the first error indication, and an erasure forecasting state table including a first field associated with first interleaved data and a second field associated with second interleaved data, the second codeword containing a first element from the first interleaved data and a second element from the second interleaved data.

### FIELD OF THE DISCLOSURE

This disclosure relates generally to communication systems and, more particularly, to methods and apparatus to perform erasure forecasting in communication systems.

### BACKGROUND

In communication systems and/or networks, data is delivered from a transmitting device to a receiving device via a communications path and/or channel. Due to, for example, noise and/or interference present on the communication path and/or channel, the communications path and/or channel has a non-zero probability of, for instance, introducing an error into and/or a loss of any given portion (e.g., packet, block, word, byte, bit, etc.) of received data. In many communication systems and/or networks some form of error correction is utilized that allows the receiving station to detect and/or correct one or more introduced errors and/or recover lost data. For example, a communication system and/or network may employ systematic forward error correction (FEC) (e.g., Reed-Solomon) that transmits a finite set of original data symbols (e.g., words, bytes, bits, etc.) together with a finite sequence of check and/or redundancy symbols (i.e., additional symbols) that are, generally, computed from the finite set of original data symbols. The original data symbols and the additional symbols are collectively referred to as an error correction codeword or simply a codeword. To provide additional error protection for longer and/or more intrusive noise events (e.g., impulse noise, micro-interruptions, etc.) codewords may be interleaved. The variety and/or depth of interleaving utilized and/or the number of additional symbols included in a codeword determine the number and/or extent of introduced errors and/or lost data that may be detected, corrected and/or recovered by a receiving station.

### BRIEF DESCRIPTION OF THE DRAWINGS

FIG. 1 is a diagram of an example communication system with a receiver constructed in accordance with the teachings of the invention.

FIG. 2 illustrates example interleaved data transmission for the example system of FIG. 1.

FIG. 3 illustrates an example manner of implementing the example (Reed-Solomon) RS decoder sub-system of FIG. 1.

FIG. 4 is an example erasure forecasting state table.

FIG. 5 illustrates an example manner of implementing the example byte-to-symbol mapper of FIG. 3.

FIG. 6 illustrates example operation of the example erasure forecaster of FIG. 3 and/or, more generally, the example RS decoder sub-system of FIG. 1 and/or 3.

FIGS. 7, 8 and 9 are flowcharts representative of example processes that may be used to implement the example erasure forecaster of FIG. 3.

FIG. 10 is a schematic illustration of an example processor platform that may be used and/or programmed to execute the example processes illustrated in FIGS. 7-9 to implement the example erasure forecaster of FIG. 3 and/or, more generally, the example RS-decoder sub-system of FIG. 1 and/or 3.

### DETAILED DESCRIPTION

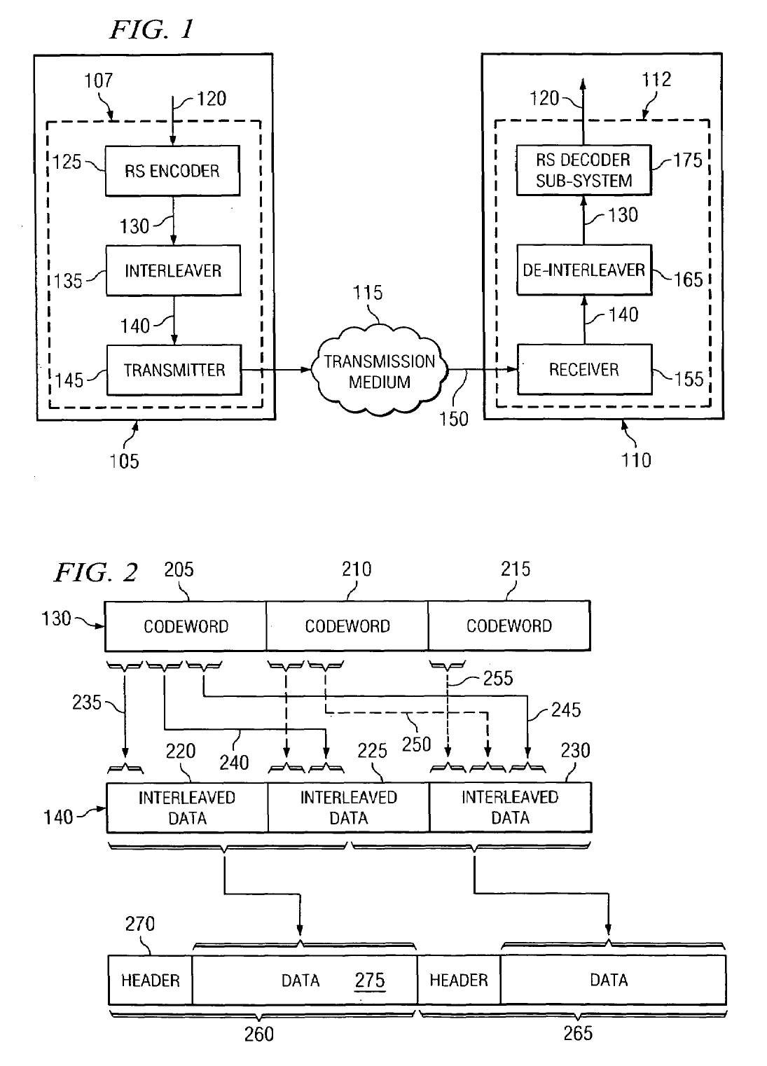

FIG. 1 is a schematic diagram of an example communication system including communication devices 105 and 110 that communicate via any of a variety of transmission media 115 (e.g., wired, wireless, etc.). To facilitate transmission of user data from the example device 105 to the example device 110 via the transmission medium 115, the example device 105 includes, among other things, a transmitter sub-system 107. Likewise, to receive the transmitted data, the example device 110 includes, among other things, a receiver sub-system 112.

The example devices 105, 110 may operate, implement and/or communicate via and/or in accordance with any of a variety of communication standard(s), technology(-ies) and/or method(s). For example, the example devices 105, 110 of FIG. 1 may implement any of a variety and/or variant of current and/or future digital subscriber line (DSL) technology such as, for example, Asymmetric DSL (ADSL), High-speed DSL (HDSL), Symmetric DSL (SDSL), and/or Very high-speed DSL (VDSL) and utilize a transmission media 115 that includes a telephone line (e.g., a ordinary twisted-pair copper telephone line used to provide Plain Old Telephone System (POTS) services). Such DSL technologies are commonly implemented in accordance with one or more applicable standards such as, for example, the International Telecommunications Union (ITU) standards G.992.1 (a.k.a. G.dmt), G.992.3, G.992.5 for ADSL modems, the ITU standard G.993.2 for VDSL, and/or the ITU standard G.994.1 (G.hs) for modems implementing handshake. Example devices 105, 110 includes a DSL modem, a DSL access multiplexer (DSLAM), a residential gateway (RG), a personal computer (PC), and/or a set-top box (STB).

While, for purposes of illustration, the following disclosure is made with respect to example digital subscriber line (DSL) equipment, DSL services, DSL systems and/or the use of ordinary telephone lines for distribution of DSL services, persons of ordinary skill in the art will readily appreciate that the methods and apparatus to perform erasure forecasting disclosed herein may additionally and/or alternatively be applied to any type and/or variety of current and/or future communication equipment, communication services, communication technologies, communication networks and/or communication systems. For example, wireless distribution systems, wired or cable distribution systems, coaxial cable distribution systems, Ultra High Frequency (UHF)/Very High Frequency (VHF) radio frequency systems, satellite or other extra-terrestrial systems, cellular distribution systems, power-line broadcast systems and/or fiber optic networks. Alternatively and/or additionally, combinations of these devices, systems and/or networks may also be used.

For further purposes of illustration, the following disclosure is made with respect to codewords, interleaved data, encoding, decoding, interleaving and/or de-interleaving based on bytes. However, persons of ordinary skill in the art will readily appreciate that codewords, interleaved data, encoding, decoding, interleaving and/or de-interleaving may be based on any of a variety of elements and/or symbols such as, for example, bits, words, multiple bytes, packets, etc.

In further detail, the example transmitter sub-system 107 of FIG. 1 transmits user and/or control data and/or information 120. The example data 120 may be provided to and/or be otherwise obtained by the example transmitter sub-system 107 and/or, more generally, the example device 105 via any of a variety of interface(s) and/or method(s). An example ADSL modem 105 includes any of a variety of Ethernet interfaces (not shown) to receive data 120 from any of a variety of user device(s) communicatively coupled to the example device 105 (e.g., a PC).

To apply forward error correction to the data and/or information 120 prior to transmission via the transmission medium 115, the example transmitter sub-system 107 includes any of a variety of forward error correction encoders 125 such as an RS encoder. During operation of the example transmitter sub-system 107 of FIG. 1, the data and/or information 120 is passed to the example RS encoder 125, which applies any of a variety and/or variant of RS FEC to blocks of bytes of the data and/or information 120 to form a sequence of codewords 130. Using any of a variety of technique(s), method(s) and/or algorithm(s), the example RS encoder 125 of FIG. 1 performs encoding in accordance with methods and/or parameters described and/or specified in, for example, the ITU standards for ADSL modems (e.g., G.992.1, G.992.3, G.992.5).

To interleave the sequence of codewords 130, the example transmitter sub-system 107 of FIG. 1 includes any of a variety of interleavers 135. Using any of a variety of technique(s), method(s) and/or algorithm(s), the example interleaver 135 of FIG. 1 interleaves the sequence of codewords 130 to form interleaved data 140. Because of the interleaving applied by the example interleaver 135, each segment and/or period of the interleaved data 140 contains bytes from one or more of the codewords 130. Likewise, bytes of a particular codeword 130 are spread among one or more segments and/or periods of the interleaved data 140. As such, the partial and/or whole corruption of a portion of the interleaved data 140 results in corresponding errors in one or more received codewords (e.g., codewords 130) at a subsequent receiver (e.g., the example receiver sub-system 112). However, since due to the interleaving each of the affected received codewords 130 have correspondingly fewer corrupted bytes, the likelihood that a RS decoder (e.g., a RS decoder sub-system 175) at the receiver 112 can detect and/or correct the affected bytes in the affected received codewords 130 is increased. Interleaving, as described above, provides additional protection against, for example, impulse noise and/or micro-interruptions that may affect one or more interleaved periods and/or segments, data frames and/or DMT frames by spreading a correctable number of errors into a correspondingly larger number of received codewords 130.

To transmit the interleaved data 140 via the transmission medium 115, the example transmitter sub-system 107 of FIG. 1 includes any of a variety of transmitters 145. An example transmitter 145 transmits the interleaved data 140 via discrete-multitone (DMT) symbols and/or signals by performing, among other things, trellis coding, data frame creation, bit-to-tone mappings, constellation encodings, inverse discrete Fourier transforms, parallel-to-serial conversions, upsampling, filtering, digital-to-analog conversions and/or amplification in accordance with current and/or future ITU standards for ADSL modems (e.g., G.992.1, G.992.3, G.992.5). An example relationship between the codewords 130, the interleaved data 140 and transmitted signals (e.g., DMT symbols) is discussed below in connection with FIG. 2.

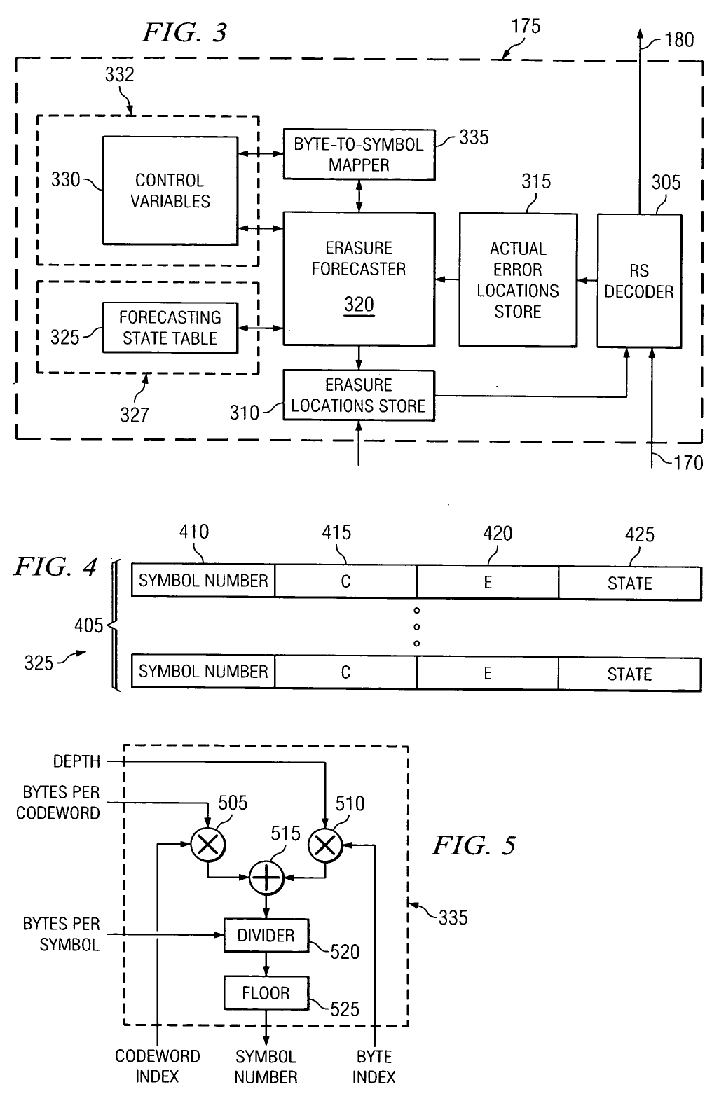

The example receiver sub-system 112 of FIG. 1 receives and/or decodes signals 150 (e.g., DMT symbols 150) received via the transmission medium 115. To receive the signals 150, the example receiver sub-system 112 of FIG. 1 includes any of a variety of receivers 155. An example receiver 155 extracts received interleaved data 140 from a received DMT signal and/or symbols 150 by performing, among other things, gain control, filtering, analog-to-digital conversions, down-sampling, equalization, discrete Fourier transforms, serial-to-parallel conversions, constellation decoding, trellis decoding, tone-to-bit mappings and/or payload extraction in accordance with current and/or future ITU standards for ADSL modems (e.g., G.992.1, G.992.3, G.992.5). The example receiver 115 of FIG. 1 and/or, more generally, the example receiver sub-system 112 keep a running count of received DMT symbols 150. The index of the DMT symbols 150 will be used by the example RS decoder sub-system 175 of FIG. 1 as described below in connection with FIGS. 3-9. It will be apparent to persons of ordinary skill in the art that to facilitate communication, the example receiver 155 and the example transmitter 145 of FIG. 1 receive and transmit signals using compatible and/or interoperable parameter(s), method(s), technique(s), algorithm(s) and/or in accordance with any of a variety of interoperable current and/or future standards.

To de-interleave the received interleaved data 140, the example receiver sub-system 112 of FIG. 1 includes any of a variety of de-interleaver 165. Using any of a variety of technique(s), method(s) and/or algorithm(s), the example de-interleaver 165 of FIG. 1 deinterleaves the received interleaved data 140 to form a sequence of received codewords 130. Like the example transmitter 145 and the example receiver 155, the example interleaver 135 and the example de-interleaver 165 perform interleaving and de-interleaving using compatible and/or interoperable parameter(s), method(s), technique(s), algorithm(s) and/or in accordance with any of a variety of interoperable current and/or future standards. For example, utilizing a common interleaver depth and/or codeword size.

To decode the received codewords 130, the example receiver sub-system 112 of FIG. 1 includes a RS decoder sub-system 175 constructed in accordance with the teachings of the invention. The example RS decoder sub-system 175 performs RS decoding to decode the received codewords 130 to obtain received user and/or control data and/or information 120. In particular, the example RS decoder sub-system 175 of FIG. 1 performs (a) erasure forecasting to identify probable locations of byte errors (i.e., erasures, erasures locations) and (b) RS decoding, error correction and/or error detection based on the erasures to obtain the received user and/or control data and/or information 120. The example RS decoder sub-system 175 and/or, more generally, the example receiver sub-system 112 of FIG. 1 keep a running count of received codewords 130. The index of the received codewords 130 is used by the example RS decoder sub-system 175 of FIG. 1 as described below in connection with FIGS. 3-9. Any of a variety of method(s) and/or technique(s) may be used to limit the number of bits required to implement the codeword index. For example, the codeword index could be maintain modulo 2^{t}, where t is chosen based upon the maximum number of received codewords 130 that need be tracked and/or referred to in the receiver sub-system 112 (e.g., at least the product of the maximum number of DMT symbols that may affect any given received codeword 130 and the maximum number of codewords 130 having at least one byte in any given DMT symbol).

Persons of ordinary skill in the art will appreciate that, although the same reference numerals are used to refer to the data 120, the codewords 130 and the interleaved data 140, the data 120, the codeword 130 and/or the interleaved data 140 at the transmitter 105 and receiver 110 may be different due to noise, errors, etc. For example, the codewords 130 at the receiver 110 represent possibly modified versions of the codewords 130 at the transmitter 105 and, thus, may or may not constitute actual codewords due to, for example, a loss of frame and/or synchronization. However, since the received codewords 130 will be subsequently decoded by the RS decoder sub-system 175 as codewords for ease of discussion they will simply be referred to herein as received codewords 130.

If the received codewords 130 contain no byte errors due to noise and/or interference, the received data 120 will be identical to the transmitted data 120. Additionally or alternatively, if the number of errors in a particular received codeword 130 does not exceed the error correction capability of the RS decoder sub-system 175, the RS decoder sub-system 175 of FIG. 1 is able to correct the errors and, again, the received data 120 will be identical to transmitted data 120. Persons of ordinary skill in the art will readily recognize that the error correction capability of the example RS decoder sub-system 175 is R/2 if we don't know the locations of errors, where R is the number of redundancy and/or check bytes added to a transmitted codeword (e.g., the codewords 130) by a corresponding RS encoder (e.g., the example RS encoder 125 of FIG. 1). Persons of ordinary skill in the art will also readily recognize that if the locations of errors are know and erasure decoding is performed by the example RS decoder sub-system 175 of FIG. 1, then the example RS decoder sub-system 175 can have an error correction capability as large as R symbols. However, to perform erasure decoding, the example RS decoder sub-system 175 needs to know, be told, determine and/or estimate which bytes are and/or are likely to be in error.

As discussed below in connection with FIGS. 3-9, to obtain increased error correction capability, the example RS decoder sub-system 175 of FIG. 1 performs erasure forecasting to determine and/or predict which bytes of which received codewords have a reasonable likelihood of being in error, and then marks such bytes for erasure during subsequent RS decoding. As used commonly in the industry, such identified error locations are referred to as “erasures” and/or “erasure locations” since the example RS decoder sub-system 175 “erases” the data in the erased locations (i.e., sets the data to zero) prior to the start of RS decoding.

The RS decoder sub-system 175 of the illustrated example exploits the properties and/or parameters (e.g., convolutional interleaving, triangular interleaving, interleaving depth, codeword size, number of interleaved bit and/or bytes transported in a DMT symbol, etc.) of the example interleaver 135, the example transmitter 145, the example receiver 155 and/or the example de-interleaver 165 to detect which, if any, DMT symbols 150 are, and/or are likely to be, affected and/or corrupted by, for example, impulse noise. Once corrupted and/or affected received DMT symbols 150 are detected, the example RS decoder sub-system 175 erases not yet decoded bytes associated with the affected and/or corrupted received DMT symbols 150 (i.e., knows the locations of errored and/or potentially errored bytes), thereby increasing the error correction capability of example RS decoder sub-system 175 by as much as a factor of two. In general, the example RS decoder sub-system 175 of FIG. 1 monitors for actual errors associated with received DMT symbols 150, uses the actual errors to detect corrupted and/or affected received DMT symbols 150, and then erases bytes associated with the corrupted and/or affected received DMT symbols 150. An example implementation of the example RS-decoder sub-system 175 of FIG. 1 is discussed below in connection with FIG. 3.

While the methods and apparatus disclosed herein detect error events based on errors associated with DMT symbols 150 and/or erase bytes associated with corrupted DMT symbols 150, persons of ordinary skill in the art will readily appreciate that the detection of error events and the determination of which bytes to erase may be made based upon any unit, period, segment and/or interval of the interleaved data 140. For example, error event detection and/or erasure decisions may be based upon DMT symbols 150, interleaver periods and/or segments, and/or data frames.

While example devices 105, 110, an example transmitter sub-system 107 and an example receiver sub-system 112 have been illustrated in FIG. 1, the elements, modules, logic, sub-systems and/or devices illustrated in FIG. 1 may be combined, re-arranged, eliminated and/or implemented in any of a variety of ways. Further, the example devices 105, 110, the example transmitter sub-system 107 and/or the example receiver sub-system 112 may be implemented by hardware, software, firmware and/or any combination of hardware, software and/or firmware. Moreover, the example devices 105, 110, the example transmitter sub-system 107 and/or the example receiver sub-system 112 may include additional elements, modules, logic, sub-systems and/or devices than those illustrated in FIG. 1 and/or may include more than one of any or all of the illustrated elements, modules, subsystems and/or devices. For example, the devices 105, 110 may include a digital signal processor (DSP), the device 105 may include a receiver sub-system and/or the device 110 may include a transmitter sub-system to allow the device 110 to transmit data and/or information to the device 105. Additionally or alternatively, the transmitter sub-system 107 may include more than one RS encoder 125 and/or more than one interleaver 135 so that the transmitter sub-system 112 and/or, more generally, the device 105 can support multiple latency paths as described in, for example, the ITU G.992.3 standard.

FIG. 2 illustrates example relationships between codewords, interleaved data and transmitted data frames and/or DMT symbols for the example system illustrated in FIG. 1. Starting with a sequence of codewords 130, three of which are shown in FIG. 2 with reference numerals 205, 210 and 215, the example interleaver 135 of FIG. 1 forms interleaved data 140. The example interleaver 135 of FIG. 1 outputs a segment and/or portion of the interleaved data 140 each time the interleaver 135 operates, three of which are shown in FIG. 2 with reference numerals 220, 225 and 230. While the interleaved data segments 220, 225 and 230 are illustrated in FIG. 2 as having the same length as the codewords 130, the interleaved data segments 220, 225 and 230 need not have the same length and/or size as the codewords 130. As illustrated in FIG. 2, example portions 235, 240 and 245 of the example codeword 205 (e.g., containing one or more bytes) are placed by the interleaver 135 into interleaved data segments 220, 225 and 230, respectively. Likewise, the example interleaved data segment 230 includes example portions 245, 250 and 255 of the example codewords 205, 210 and 215, respectively. Persons of ordinary skill in the art will readily appreciate that the number of interleaved data segments 140 that a particular codeword 130 is interleaved into and/or the number of codewords 130 having bytes in a particular interleaved data segment 140 depends upon the interleaving parameter(s) of the interleaver 135 (e.g., interleaver depth d) and/or the number of bytes k in each of the codewords 130.

In the illustrated examples of FIG. 1 and/or 2, a portion of the interleaved data 140 is used to form transmit data frames, two of which are illustrated in FIG. 2 with reference numerals 260 and 265. In the illustrated example of FIG. 2, each of the example transmit data frames 260 and 265 include a portion of two interleaved data segments 220, 225 and/or 230. The example transmit data frame 260 of FIG. 2 includes (a) a header 270 that contains, for example, control information regarding the data frame 260 and (b) a data payload 275 that contains the one or more portions of one or more interleaved data segments 220, 225 and/or 230. Persons of ordinary skill in the art will readily appreciate that the number and/or size of portions of interleaved data 140 used to form the payload (e.g., the payload 275) of a transmit data frame (e.g., the data frame 260) depends upon the size of the payload (e.g., number of bits and/or bytes P) and/or the number of bytes N in each of the interleaved codewords 140.

In the example transmitter sub-system 107 of FIG. 1, transmit data frames 260, 265 are modulated and/or transmitted via the transmission medium 115 to a receiver (e.g., the example receiver sub-system 112). In the example system of FIG. 1, the transmitter sub-system 107 transmits and/or modulates the transmit data frames 260, 265 in accordance with an ADSL standard such as, for example, the ITU G.992.1, G.992.3 and/or G.992.5 standards, where each transmit data frame 260, 265 is transmitted via one or more DMT symbols. The example data frames 260, 265 may represent any portion of the data carried by any number of DMT symbols. That is, the number of bits and/or bytes in each of the data frames 260, 265 need not be the same as the number of bits and/or bytes carried by any particular DMT symbol and, in fact, may be larger or smaller. The number of bits and/or bytes P carried in each DMT symbols depends upon the transmit data rate (e.g., bits per second) of the transmitter sub-system 107. Moreover, even if the codewords 130 and/or the interleaved data 140 are based on bytes, neither the data frames 260, 265 nor resultant DMT symbols need be based on bytes but may be based on bits, bytes and/or words. However, any of a variety of alternative and/or additional method(s), algorithm(s), technique(s) and/or standard(s) may be used to transmit and/or modulate transmit data frames (e.g., quadrature amplitude modulation (QAM)).

At a receiving device (e.g., the example device 110 of FIG. 1), the process described above is performed in reverse order. Namely, a signal (e.g., the example received DMT symbols 150 of FIG. 1) is received and/or demodulated by a receiver (e.g., the example receiver 155 of FIG. 1) to form and/or obtain a received version of the transmit data frames 260, 265 (i.e., received data frames 260, 265). For example, a DMT symbol is received and/or decoded to recover the payload data 275 for any or all of one or more data frames and, thus, one or more portions of one or more interleaved data segments 220, 225 and/or 230. If no noise is present on the line, then received data frames 260, 265 will be substantially similar to the transmit data frames 260, 265. Any difference(s) represents errors due to transmission via the transmission medium 115 (e.g., impulse noise, cross-talk noise, background noise, etc.) and/or implementation limitations of the device 105 and/or 110 (clipping, saturation, linearity, etc.). The payloads of received data frames 260, 265 are used to form received interleaved data (e.g., the example received interleaved data 140 of FIG. 1) that are de-interleaved by a de-interleaver (e.g., the example de-interleaver 165 of FIG. 1) to form received codewords (e.g., the received codewords 130 of FIG. 1). Next, the received codewords 130 are decoded by an RS decoder (e.g., the example RS decoding sub-system 175 of FIG. 1) to obtain received user and/or control data and/or information (e.g., the example data 120 of FIG. 1).

Persons of ordinary skill in the art will readily appreciate that when transmit data frames (e.g., the example frames 260 and 265) are transmitted via DMT symbols, an impulse noise event can cause signal degradation such that the payload 275 and/or header 270 of one or more transmit data frames 260, 265 may be partially and/or wholly corrupted. When and/or if such data frame and/or header corruption occurs corresponding portions of received interleaved data 140 and/or received codeword(s) 130 may be wholly and/or partially errored. The number and/or location of affected bytes within the received codeword(s) 130 depends upon the properties and/or parameters of the interleaver 135, the example transmitter 145, the example receiver 155 and/or the example de-interleaver 165 (e.g., convolutional interleaving, triangular interleaving, interleaving depth, codeword size, number of interleaved bytes transported in a DMT symbol, etc.).

Consider an example impulse noise event that corrupts one or more DMT symbols. If sufficient interleaving is applied by the interleaver 135 so that at most R bytes of any received codeword 130 are associated with any or all of the one or more corrupted DMT symbol, collectively, then, if the example RS decoder sub-system 175 of FIG. 1 detects the corrupted DMT symbols, the example RS decoder sub-system 175 can again utilize erasure decoding to correct all errors in the received codewords 130. In this example scenario, any particular received codeword 130 may have more than R/2 errored bytes (but no more than R) and, thus, RS decoding without the use of erasures may not be able to correctly decode each received codeword 130. By performing erasure forecasting to detect corrupted DMT symbols, and then exploiting properties of the interleaver to determine appropriate erasure locations, the example RS decoder sub-system 175 of FIG. 1 improves the error correction capabilities of the example device 110. The RS decoder sub-system 175 of FIG. 1 handles, for example, impulse noise events that corrupt a variable number of DMT symbols.

FIG. 3 illustrates an example manner of implementing the example RS decoder sub-system 175 of FIG. 1. To perform RS decoding, the example RS decoder sub-system 175 of FIG. 3 includes any of a variety of RS decoder 305. Using any of a variety of method(s), algorithm(s), logic and/or technique(s), the example RS decoder 305 of FIG. 3 performs RS decoding and/or erasure decoding of received codewords 130. For example, the RS decoder 305 uses Euclid's algorithm and a Chien search to decode the received codewords 130. In the example of FIG. 3, received codewords contain a maximum of 255 bytes.

To improve the error correction capability, the example RS decoder sub-system 175 includes an erasure locations store 310. The example erasure locations store 310 of FIG. 3 is implemented as sixteen (16) eight (8)-bit registers. However, the erasure locations store 310 may be implemented by any of a variety and/or number of memories, registers, etc. The 256 bits of the example erasure locations store 310 of FIG. 3 indicate whether a respective byte of a given received codeword 130 is to be erased. As discussed below, the erasure locations store 310 will be updated prior to the decoding of each received codeword 130 by the example RS decoder 305. Using any of a variety of method(s), algorithm(s), logic and/or technique(s), the example RS decoder 305 utilizes the data in the erasure locations store 310 to perform erasure decoding during the decoding of the received codewords 305.

To store indications of errored bytes, the example RS decoder sub-system 175 of FIG. 3 includes actual error locations store 315. The example actual error locations store 315 of FIG. 3 is implemented as sixteen (16) eight (8)-bit registers. However, the actual error locations store 315 may be implemented by any of a variety and/or number of memories, registers, etc. The 256 bits of the example actual error locations store 315 of FIG. 3 indicate whether an error of a respective byte of a given received codeword 130 was detected and/or corrected by the example RS decoder 305. That is, the example actual error locations store 315 identify byte locations having a different value at the input 130 and output 120 of the example RS decoder 305 and, thus, may include bytes that were corrected by the example RS decoder 305. The actual error locations store 315 is updated by the example RS decoder 305 after the decoding of each received codeword 130.

To determine erasure locations, the example RS decoder sub-system 175 of FIG. 3 includes an erasure forecaster 320. The example erasure forecaster 320 of FIG. 3: (a) utilizes the actual error locations store 315 for one or more previously decoded received codewords 130 to determine if and/or which received DMT symbols 150 are affected and/or corrupted, and (b) if received DMT symbols 150 are affected and/or corrupted, sets and/or indicates erasure locations in the erasure locations store 310 for the affected bytes of received codewords 130. If no DMT symbols 150 are affected and/or corrupted, no erasures are indicated in the erasure locations store 310 by the example erasure forecaster 320. As discussed below in connection with FIGS. 4-9, the example erasure forecaster 320 of FIG. 3 utilizes the properties of the interleaver to determine which bytes of which codewords are associated with particular received DMT symbols 150.

In the illustrated example of FIG. 3, the example stores 310 and 315 store erasure locations and actual error locations, respectively for single codewords. However, the stores 310 and/or 315 may store data for more than one codeword. For example, the erasure forecaster 320 may utilize actual error locations from the store 315 for two or more codewords and then determine and/or store erasure locations in the store 310 for the next one or more codewords to be decoded.

The erasure forecaster 320 of the illustrated example tracks, for each of one or more DMT symbols 150, the number of previously decoded bytes and the number of errored bytes. An example structure for use in tracking each DMT symbol 150 is discussed below in connection with FIG. 4. In general, the example erasure forecaster 320 of FIG. 3 uses the ratio of the number of errored bytes to the number of decoded bytes for a particular DMT symbol 150 as a metric of the extent to which that particular DMT symbol 150 is affected and/or corrupted. If the ratio is high enough (e.g., equals or exceeds a predetermined threshold such as 75%), the example erasure forecaster 320 make a soft decision and decides and/or declares that the DMT symbol 150 is corrupted and marks subsequently decoded bytes associated with the DMT symbol 150 for erasure. While the example erasure forecaster 320 of FIG. 3 uses the ratio of the number of errored bytes to the number of decoded bytes to make soft erasure decisions, any decision metric such as comparing the number of errored bytes to a threshold may additionally or alternatively be used. The erasure forecaster 320 may also be selectively configured to use the ratio and/or the number of errored bytes to make erasure decisions. For a DMT symbol 150 that has been declared as corrupted, the example erasure forecaster 320 of FIG. 3 determines if any bytes associated with the DMT symbol 150 are present in the next received codeword 130 to be decoded. If there are bytes associated with the corrupted DMT symbol 150 present in the next received codeword 130, the example erasure forecaster 320 of FIG. 3 instructs the RS decoder 305 to erase the bytes by, for example, setting the respective bit(s) in the example erasure location registers 310 to one (1).

Once a pre-determined number of bytes have been decoded for a particular data frame, the example erasure forecaster 320 of FIG. 3 makes a final (i.e., hard) decision whether the DMT symbol 150 is affected and/or corrupted. The final decision for a given DMT symbol 150 is based on the ratio of the number of errored bytes to the number of already decoded bytes for the DMT symbol 150 and is made by comparing the ratio to the same or to a different threshold (e.g., such as 65%). If the ratio equals or exceeds the threshold, then the example erasure forecaster 320 of FIG. 3 marks all subsequent decoded bytes associated with the DMT symbol 150 for erasure via the example erasure location registers 310. If the ratio does not exceed the threshold, none of the subsequently decoded bytes associated with the DMT symbol 150 are marked for erasure by the example erasure forecaster 320. While the example erasure forecaster 320 of FIG. 3 uses the ratio of the number of errored bytes to the number of decoded bytes to make hard erasure decisions, any decision metric such as comparing the number of errored bytes to a same or different threshold may additionally or alternatively be used. The erasure forecaster 320 may also be selectively configured to use the ratio and/or the number of errored bytes to make erasure decisions. The example erasure forecaster 320 of FIG. 3 need only track the number of decoded and/or errored bytes for a particular DMT symbol 150 until a hard decision is made.

Prior to the hard decision for a particular data frame, the example erasure forecaster 320 of FIG. 3 makes a decision on a codeword by codeword basis (i.e., a soft decision) whether to erase bytes associated with the DMT symbol 150 in the next received codeword. After each received codeword 130 is decoded by the RS decoder 305, the example erasure forecaster 320 reads the actual error location registers 315 and updates the number of decoded bytes and errored bytes for each DMT symbol 150 having bytes in the received codeword 130 and currently being tracked (i.e., DMT symbol 150 for which no hard decision has been made). Then, for each DMT symbol 150 having one or more bytes in the next received codeword 130, the example erasure forecaster 320 of FIG. 3 determines which bytes associated with which data frame(s) should be erased and sets the corresponding bits in the example erasure location registers 310. Like hard decisions, soft decisions are made by comparing the ratio of the number of errored bytes to the number of already decoded bytes for the DMT symbol 150 to a threshold such as 75%. However, unlike hard decisions which apply to the remainder of a data frame, a soft decision only applies to the next received codeword 130. The threshold used for making soft decisions may be the same or different from that used for making hard decisions. While the example erasure forecaster 320 of FIG. 3 makes both soft and hard erasure decisions, the erasure forecaster 320 may simply utilize either soft or hard decisions.

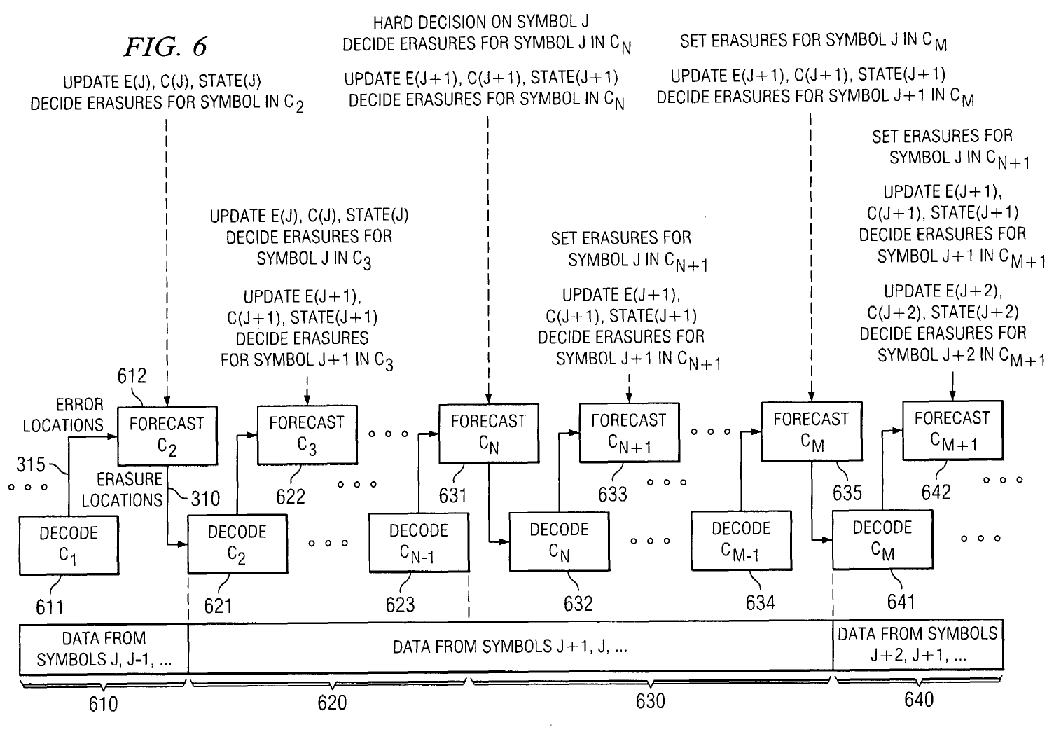

As discussed below in connection with FIG. 6, soft and/or hard decisions for each DMT symbol 150 may be independent, dependent, related and/or inter-coupled. Moreover, time intervals over and/or during which soft and/or hard decisions are made for one or more DMT symbols 150 may be disjoint and/or partially and/or wholly overlap. Consider, for example, a first time interval during which the example erasure forecaster 320 of FIG. 3 tracks and makes soft decisions related to a first data frame. During a second time interval that follows the first time interval, the example erasure forecaster 320 tracks and makes soft decisions related to the first and a second data frame. At the start of a third time interval that follows the second time interval, the example erasure forecaster 320 makes a hard decision regarding corruption of the first data frame. Then, during the remainder of the third time interval, the erasure forecaster 320 continues tracking and making soft decisions related the second DMT symbol 150 and marks erasures (i.e., decides to erase) based on the hard decision for the first data frame. Persons of ordinary skill in the art will readily appreciate that the example erasure forecaster 320 of FIG. 3 may, thus, track and make hard and/or soft decisions for two or more DMT symbols 150 over any combination of overlapping and/or non-overlapping time intervals. Example manners of implementing the example erasure forecaster 320 and/or, more generally, the example RS decoder sub-system 175 of FIG. 3 are discussed below in connection with FIGS. 6-9.

If a receiver (e.g., the example receiver sub-system 112 of FIG. 1) implements multiple latency paths, then erasure forecasting can be performed for the latency paths independently or dependently. If the latency paths are considered separately, then errors are tracked and erasure decisions made for each latency path separately. That is, an impulse noise can be detected and erasures made in one latency path while a second latency path having sufficient impulse noise protection and/or not exhibiting the same interference does not warrant and/or benefit from erasures.

To store the data necessary and/or useful to track errors and/or make erasure decisions (i.e., erasure forecasting), the example RS decoder sub-system 175 of FIG. 3 includes an erasure forecasting state table 325. An example data structure to implement the example erasure forecasting state table 325 of FIG. 3 is discussed below in connection with FIG. 4. The example erasure forecasting state table 325 may be stored in any of a variety of memory(-ies), register(s), etc. 327. Persons of ordinary skill in the art will also readily appreciate that the maximum number of DMT symbols 150 that may affect any given received codeword 130 (i.e., maximum number of active DMT symbols 150) depends upon the parameters and/or properties of the interleaving/de-interleaving. Thus, for a given set and/or range of interleaving/de-interleaving parameters and/or properties supported by a given receiver (e.g., the example receiver 110 of FIG. 1), the maximum number of active DMT symbols 150 for which erasure forecasting is required is correspondingly limited. Accordingly, the example erasure forecasting state table 325 of FIG. 3 stores data associated with active DMT symbols 150, and overwrites and/or discards data associated with inactive frames (e.g., frames which are no longer for further decoding). In the example RS decoder 175 of FIG. 3, the maximum number of DMT symbols 150 that are simultaneously considered is a power of 2 (i.e., 2^{M}), where 2^{M} is at least equal to the maximum number of active frames. That is, the forecasting state table 325 stores at least enough data to allow the maximum number of active frames to be considered. The example erasure forecasting state table 325 of FIG. 3 is indexed using a DMT symbol 150 counter and/or index modulo 2^{M}. That is, the lowest M-bits of the frame number can be used to index the example forecasting state table 325.

To store parameters that specify the current properties and/or parameters of the RS decoding and/or de-interleaving being applied to the received interleaved data 140 and/or the received codewords 130, the example RS decoder sub-system 175 of FIG. 3 includes control variables 330. The control variables 330 may be stored in any of a variety of memory(-ies), register(s), etc. 332. Example control variables 330 include: (i) interleaver depth d, (ii) codeword size k, (iii) number of interleaved bits and/or bytes P per DMT symbol 150 and/or DMT symbol, (iv) maximum number of erasures per codeword R, (v) threshold for soft erasure decisions and/or (vi) threshold for hard decisions.

To compute which DMT symbol 150 corresponds to a particular byte of a particular codeword, the example RS decoder sub-system 175 of FIG. 3 includes a byte-to-symbol mapper 335. Using one or more variables from the example control variables 330, and a byte index and a codeword index provided by the example erasure forecaster 320, the example byte-to-symbol mapper 335 of FIG. 3 computes and/or determines the DMT symbol 150 in which the specified byte of the specified codeword was transmitted and/or received. In the illustrated example of FIG. 3, the byte index identifies each byte within a codeword 130 with the right-most byte of a codeword 130 (i.e., first byte of the codeword 130 out of the de-interleaver 165) given a byte index of zero (0). The example byte-to-symbol mapper 335 of FIG. 3 may, for example, compute the DMT symbol 150 index corresponding to the k-th byte of the i-th codeword using the following mathematical expression:

$$Frame\_Index = ⌊ \frac{N * i + k * d}{P} ⌋ , \qquad EQN ( 1 )$$

where N is the number of bytes per codeword 130, d is the de-interleaver depth, P is the number of bytes per DMT symbol 150, and └ ┘ represents the floor operator. An example manner of implementing the example byte-to-symbol mapper 335 of FIG. 3 is discussed below in connection with FIG. 5.

In an example receiver (e.g., the example receiver sub-system 112 of FIG. 1), the example erasure forecaster 320 of FIG. 3 is implemented as hard-coded logic and/or discrete gates, and the example RS decoder sub-system 175 of FIG. 1 and/or 3 is communicatively coupled to any of a variety of processors (e.g., a DSP) for any of a variety of control and/or debug purposes. The example erasure forecaster 320 of the illustrated example may be disabled such that, for example, the communicatively coupled processor may access the actual error locations store 315, perform erasure forecasting (i.e., track error, error patterns and/or make erasure decisions) and/or provide the contents of the erasure locations store 310. The communicatively coupled processor can implement any of a variety of additional and/or alternative erasure forecasting algorithm(s), method(s), logic(s), and/or technique(s).

Additional and/or alternative example methods and apparatus to implement the example erasure forecaster 320, the example byte-to-symbol mapper 335 and/or, more generally, the example RS decoder sub-system 175 of FIG. 1 and/or 3 are described in U.S. patent application Ser. No. 11/159,476 filed on Jun. 23, 2005 which is hereby incorporated by reference in its entirety.

While an example RS decoder sub-system 175 has been illustrated in FIG. 3, the elements, modules, logic, sub-systems and/or devices illustrated in FIG. 3 may be combined, re-arranged, eliminated and/or implemented in any of a variety of ways. Further, the example RS decoder 305, the example erasure locations store 310, the example actual error locations store 315, the example erasure forecaster 320, the example erasure forecasting state table 325, the example control variables 330 and/or the example byte-to-symbol mapper 335 may be implemented by hardware, software, firmware and/or any combination of hardware, software and/or firmware. For example, the example erasure forecaster 320 may be implemented as machine accessible instructions executing on any of a variety of processors. Moreover, the example RS decoder sub-system 175 may include additional elements, modules, logic, sub-systems and/or devices than those illustrated in FIG. 3 and/or may include more than one of any or all of the illustrated elements, modules, sub-systems and/or devices. For example, the RS decoder sub-system 175 may include a second RS decoder 305 to decode codewords associated with a second latency path.

FIG. 4 illustrates an example data structure 325 for storing variables and/or data which is useful to erasure forecasting. The example erasure forecasting state table 325 of FIG. 4 contains a plurality of entries 405 for respective ones of DMT symbols 150 that are being tracked and/or for which erasure decisions are being made. As discussed above, the number of entries 405 is at least the maximum number of active DMT symbols 150 that can contribute at least one byte to any given codeword to be decoded at any given time and is dictated by the set and/or range of encoding/decoding and/or interleaving/de-interleaving parameters supported by the RS decoder sub-system 175 and/or, more generally, the example receiver sub-system 112 of FIG. 1 and/or 3. In the illustrated example, the number of entries 405 is a power of 2 (i.e., 2^{M}) and the entries 405 are indexed using a DMT symbol counter and/or index modulo 2^{M}. That is, the lowest M-bits of the frame number can be used to index the example forecasting state table 325 of FIG. 4

To record the actual (i.e., non-modulo) frame number and/or index, each of the example entries 405 has a frame number field 410. The example frame number field 410 of FIG. 4 contains the contents of the frame number counter as maintained by, for example, the example receiver 155 as discussed above in connection with FIG. 1.

To store the count of already decoded bytes for the active DMT symbols 150, each of the example entries 405 include a count C field 415. To store the count of errored-decoded bytes for the active DMT symbols 150, each of the example entries 405 include a count E field 420. After each received codeword 130 is decoded by the example RS decoder 305, the example erasure forecaster 320 of FIG. 3 reads the example actual error locations store 315 and updates the count C fields 415 and the count E fields 420 with the corresponding number of decoded bytes and the number or errored-decoded bytes, respectively, for each DMT symbol 150 having bytes in the received codeword 130. In the illustrated system of FIG. 1, each DMT symbol 150 can contain a maximum of 4096 bytes (i.e., a maximum of 16-bits for each of 2048 DMT carriers) and, thus, the example count C fields 415 and the example count E fields 420 of FIG. 4 are implemented by twelve (12) bit fields and/or counters.

To store an indication of the current state of erasure forecasting for the active DMT symbols 150, the example entries 405 include a state field 425. The example state fields 425 of FIG. 4 contain one of three values: (i) zero (0) indicating that the corresponding DMT symbol 150 is currently being tracked and soft decisions are being made, (ii) one (1) indicating that a hard decision to erase subsequent bytes associated with the DMT symbol 150 has been made, or (iii) two (2) indicating a hard decision not to erase subsequent bytes associated with the DMT symbol 150 has been made.

Because once a hard decision is made for a particular DMT symbol 150 the count of the number of decoded bytes and the count of the number of error bytes are no longer needed for the data frame, the example entries 405 of FIG. 4 may instead utilize one of a set of shared decoded byte counters and errored byte counter pairs and the example count C fields 415 and the example count E fields 420 of FIG. 4 may be eliminated. Thus, the example erasure forecaster 320 may implement fewer pairs of counters thereby reducing implementation complexity. For example, the erasure forecaster 320 may implement 2^{m} pairs of counters, where 2^{m} is the maximum number of frames that may currently being in a soft decision state and m<M. The counter pair for a particular DMT symbol 150 may be determined as the DMT symbol counter and/or index modulo 2^{m}.

While an example data structure 325 has been illustrated in FIG. 4, any of a variety of additional and/or alternative data structures, tables, arrays, registers, variables, etc. may be used to store the data and/or information useful to track and/or make erasure decisions. Moreover, the example data structure may include and/or store any of a variety of additional and/or alternative data and/or information associated with any or all of the DMT symbols 150 including, for example, debug information.

FIG. 5 illustrates an example manner of implementing the example byte-to-symbol mapper 335 of FIG. 3. The example byte-to-symbol mapper 335 of FIG. 5 implements the example mathematical equation illustrated in EQN (1). Additionally or alternatively, any of the methods and apparatus described in U.S. patent application Ser. No. 11/159,476 may be used to implement the example byte-to-symbol mapper 335 of FIG. 3 and/or 5.

To compute the numerator of EQN (1), the example byte-to-symbol mapper 335 of FIG. 5 includes multipliers 505 and 510, and an adder 515. The example multiplier 505 of FIG. 5 multiplies the number of bytes per codeword N with the codeword index i and the example multiplier 510 of FIG. 5 multiplies the interleaver depth d with the byte index k. The example adder 515 of FIG. 5 adds the outputs of the multipliers 505 and 510 together.

To divide the output of the example adder 515 (i.e., the numerator of the example EQN (1)), the example byte-to-symbol mapper 335 of FIG. 5 includes a divider 520. The example divider 520 of FIG. 5 divides the output of the example adder 515 by the bytes per frame P. To compute the floor of an output of the example divider 520, the example the byte-to-symbol mapper 335 of FIG. 5 includes a floor operator 525. The example floor operator 525 of FIG. 5 removes any fractional portion of the output value of the divider 525 to obtain the nearest integer value less than or equal to the output of the divider 520.

While an example byte-to-symbol mapper 335 has been illustrated in FIG. 5, the elements, modules, logic, sub-systems and/or devices illustrated in FIG. 5 may be combined, re-arranged, eliminated and/or implemented in any of a variety of ways. For example, the multipliers 505 and 510 may be implemented using a single multiplier. Further, the example byte-to-symbol mapper 335 may be implemented by hardware, software, firmware and/or any combination of hardware, software and/or firmware. Moreover, the example byte-to-symbol mapper 335 may include additional elements, modules, logic, subsystems and/or devices than those illustrated in FIG. 5 and/or may include more than one of any or all of the illustrated elements, modules, sub-systems and/or devices.

FIG. 6 illustrates an example operation of the example erasure forecaster 320 and/or, more generally, the example RS decoder sub-system 175 of FIG. 1 and/or 3. The operation of the erasure forecaster 320 is illustrated in FIG. 6 over four (4) example time intervals 610, 620, 630 and 640. As illustrated in FIG. 6, during the example time interval 610, the example RS decoder sub-system 175 is processing received codewords 130 containing data associated with DMT symbols 150j, j−1, j−2, etc. Starting with a received codeword C₁, the example RS decoder 305 decodes the received codeword C₁ as shown with reference numeral 611 and determines actual error location information 315 for the decoded received codeword C₁. Based on the error location information 315 for codeword C₁, the example erasure forecaster 320 updates the count of decoded bytes and the count of errored-decoded bytes for DMT symbol 150j, and then makes a soft decision regarding DMT symbol 150j for the next codeword C₂ as shown with reference numeral 612. The example erasure forecaster 320 may also update counters and/or make soft and/or hard erasure decisions for DMT symbols 150j−1, j−2, etc. Based upon the erasure decisions, the erasure forecaster 320 sets the values of the erasure location registers 310 for codeword C₂.

For simplicity of understanding, throughout the remainder of the discussion regarding FIG. 6, the passing of error locations via the actual error locations store 315 and erasure locations via the erasure locations store 310 between the RS decoder 305 and the erasure forecaster 320 will not be explicitly discussed. Persons of ordinary skill in the art will readily appreciate that it continues in a substantially similar fashion to that explained above. Moreover, while error tracking, soft and/or hard erasure decisions and/or setting erasures associated with DMT symbols 150j, j+1 and j+2 are discussed below, persons of ordinary skill in the art will also readily appreciate that error tracking, soft and/or hard erasure decisions and/or setting erasures for DMT symbols 150j−1, j−2, j−3 may also be occurring but, for simplicity of understanding, will also not be discussed below. However, persons of ordinary skill in the art will readily appreciate that error tracking, soft and/or hard erasure decisions and/or setting erasures for DMT symbols 150j−1, j−2, j−3, etc. may be occurring along with those for DMT symbols 150j, j+1, j+2, etc. depending upon the particular DMT symbols 150 contributing bytes to a presently considered codeword.

As illustrated in FIG. 6, during the example time intervals 620 and 630, the example RS decoder sub-system 175 is processing received codewords 130 containing data associated with DMT symbols 150j+1, j, j−1, etc. Starting with a received codeword C₂, the example RS decoder 305 decodes the received codeword C₂ as shown with reference numeral 621. Based on the actual error location information for the decoded codeword C₂, the example erasure forecaster 320 updates the count of decoded bytes and the count of errored-decoded bytes for DMT symbols 150j+1 and j, makes soft decisions regarding DMT symbols 150j and j+1, and then sets erasures for bytes associated with DMT symbols 150j and j+1 for the next codeword C₃ based on the soft decisions as shown with reference numeral 622.

Processing continues similarly till the decoding of a received codeword C_{N-1} as shown with reference numeral 623. The example codeword C_{N-1} is the last codeword of the example time interval 620.

Based on the actual error location information for the decoded codeword C_{N-1}, the example erasure forecaster 320 updates the count of decoded bytes and the count of errored-decoded bytes for DMT symbols 150j+1 and j. With the decoding of codeword C_{N-1} in the example of FIG. 6, the count of the number of decoded bytes associated with DMT symbol 150j exceeds a count threshold, the example erasure forecaster 320 makes a hard decision regarding DMT symbol 150j and sets erasures for the next codeword C_{N} for bytes associated with DMT symbol 150j based on the hard decision as shown with reference numeral 631. The erasure forecaster 320 also makes another soft decision for DMT symbol 150j+1, and sets erasures based on the soft decision for DMT symbol 150j+1 for bytes associated with frame j+1 for the next codeword C_{N}.

The RS decoder 305 then decodes codeword C_{N} as shown with reference number 632. Based on the actual error location information for the decoded codeword C_{N}, the example erasure forecaster 320 updates the count of decoded bytes and the count of errored-decoded bytes for DMT symbol 150j+1, sets erasures for the next codeword C_{N+1} for bytes associated with DMT symbol 150j based on the previously made hard decision, makes another soft decision for DMT symbol 150j+1, and sets erasures based on the soft decision regarding frame j+1 for bytes associated with DMT symbol 150j+1 the next codeword C_{N+1} as shown with reference numeral 633.

Processing continues similarly until the decoding of a received codeword C_{M-1} as shown with reference numeral 634. The example codeword C_{M-1} is the last codeword of the example time interval 630. Based on the error location information for the decoded codeword C_{M-1}, the example erasure forecaster 320 updates the count of decoded bytes and the count of errored-decoded bytes for DMT symbol 150j+1, sets erasures for the next codeword C_{M} for bytes associated with DMT symbol 150j based on the previously made hard decision, makes yet another soft decision for DMT symbol 150j+1, and set erasures based on the soft decision for DMT symbol 150j+1 for bytes associated with DMT symbol 150j+1 for the next codeword CM as shown with reference numeral 635.

As illustrated in FIG. 6, during the example time interval 640, the example RS decoder sub-system 175 is processing received codewords 130 containing data associated with DMT symbols 150j+2, j+1, j, etc. The RS decoder 305 decodes codeword C_{M} as shown with reference number 641. Based on the actual error location information for the decoded codeword C_{M}, the example erasure forecaster 320 updates the count of decoded bytes and the count of errored-decoded bytes for DMT symbols 150j+2 and j+1, sets erasures for the next codeword C_{M+1} for bytes associated with DMT symbol 150j based on the previously made hard decision, makes a soft decision for DMT symbols 150j+2 and j+1, and sets erasures based on the soft decisions for bytes associated with DMT symbols 150j+2 and j+1 for the next codeword C_{M+1} as shown with reference numeral 642.

While an example operation has been illustrated in FIG. 6, persons of ordinary skill in the art will readily recognize that the methods and apparatus disclosed herein can be used to track and/or make erasure decisions for a wide variety of conditions, examples and/or systems. For example, at reference numeral 621, where codeword C₂ has a first byte associated with DMT symbol 150j+1, and at reference numeral 622, where error tracking and/or erasure decisions are first made for DMT symbol 150j+1, the example erasure forecaster 320 of FIG. 3 could also make a hard decision regarding DMT symbol 150j. In this example, a single pair of counters to count the number of decoded bytes and the number of errored bytes is sufficient and the example forecasting state table 325 can be accordingly simplified. That is, the tracking of errors and/or the making of erasure decisions proceed serially rather than in parallel.

In another example, at reference numeral 622, the erasure forecaster 320 uses the error location information for frames j and j+1 collectively to make a simultaneous hard erasure decision regarding frames j and j+1. In this example, the erasure forecaster 320 is looking for error events that corrupt and/or affect exactly two DMT symbols 150. Once a hard decision is made to erase bytes associated with frames j and j+1, the erasure forecaster 320 waits until all bytes associated with frames j and j+1 have been decoded before tracking error location information to identify another noise event. If a hard decision is made not to erase bytes associated with frames j and j+1, the error location information for frame j+1 is used as the starting point for making a hard decision related to DMT symbols 150j+1 and j+2; once the first byte associated with DMT symbol 150j+2 is decoded.

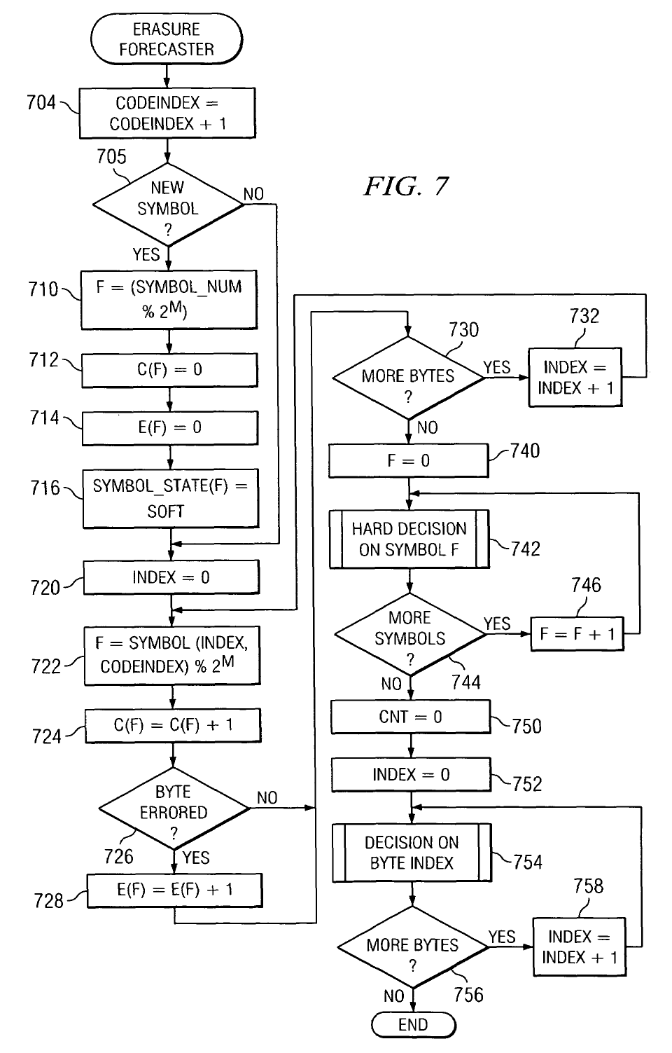

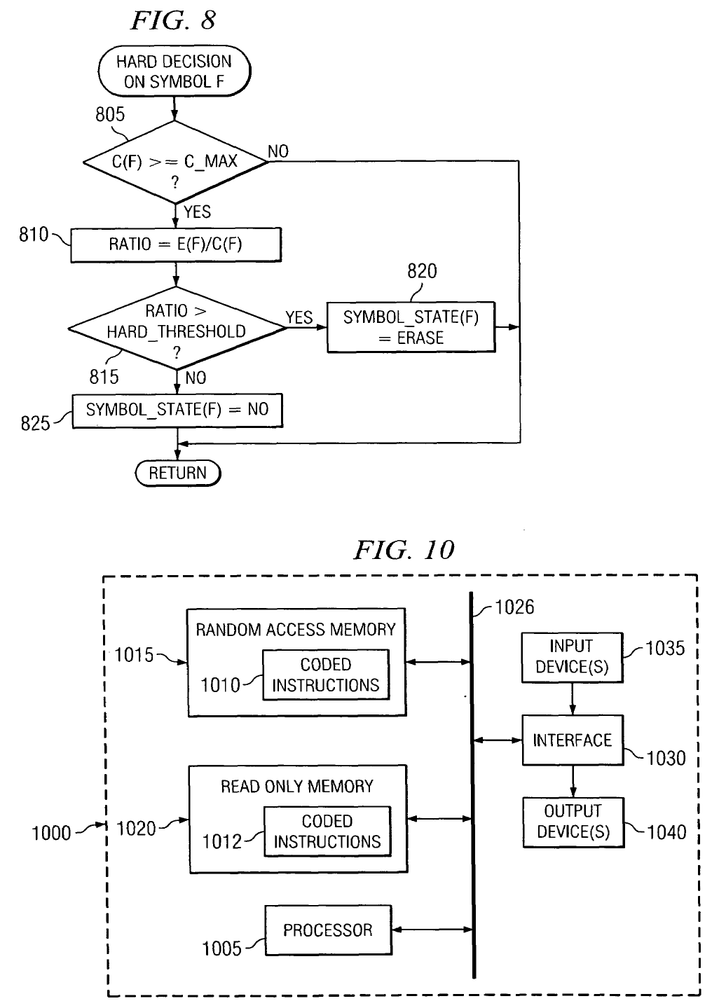

FIGS. 7, 8 and 9 are flowcharts representative of example processes that may be used to implement the example erasure forecaster 320 and/or, more generally, the example RS decoder sub-system 175 of FIG. 1 and/or 2 to perform error tracking and/or make erasure decisions (i.e., erasure forecasting). The example processes of FIGS. 7, 8 and/or 9 may be implemented using an application specific integrated circuit (ASIC), a programmable logic device (PLD), a field programmable logic device (FPLD), discrete logic, discrete gates, registers, hardware, firmware, etc. Alternatively, some or all of the example processes of FIGS. 7, 8 and/or 9 may be executed by a processor, a controller and/or any other suitable processing device (e.g., the example processor 1005 discussed below in connection with FIG. 10). For example, the example processes of FIGS. 7, 8 and/or 9 may be embodied in coded instructions stored on a tangible medium such as a flash memory, read-only memory (ROM) and/or random access memory (RAM) associated with the processor. Also, some or all of the example flowcharts of FIGS. 7, 8 and/or 9 may be implemented manually or as combinations of any of the foregoing techniques, for example, a combination of firmware and/or software and hardware. Further, although the example processes of FIGS. 7-9 are described with reference to the flowcharts of FIGS. 7-9, persons of ordinary skill in the art will readily appreciate that many other methods of implementing the example erasure forecaster 320 and/or, more generally, the example RS decoder sub-system 175 of FIG. 1 and/or 2 to perform erasure forecasting may be employed. For example, the order of execution of the blocks may be changed, and/or some of the blocks described may be changed, eliminated, sub-divided, or combined. Additionally, persons of ordinary skill in the art will appreciate that the example processes of FIGS. 7, 8 and/or 9 may be carried out sequentially and/or carried out in parallel by, for example, separate processing thread(s), processor(s), device(s), circuit(s), etc.

The example process of FIG. 7 begins when a received codeword 130 is decoded by the example RS decoder 305 and the RS decoder 305 determines actual error location information and writes it to the actual error location store 315. An erasure forecaster (e.g., the example erasure forecaster 320 of FIG. 2) increments a count of the received codewords (i.e., the codeword index) (block 704).

The erasure forecaster 320 determines if a new DMT symbol 150 has one or more bytes in the just decoded codeword (block 705). If the just decoded codeword has one or more bytes from a new DMT symbol 150 (block 705), the erasure forecaster determines the corresponding index into the erasure forecasting state table 325 by computing the modulo 2^{M} of the DMT symbol 150 number where 2^{M} is the maximum number of active DMT symbols 150 (block 710). The erasure forecaster than sets, for the new active DMT symbol 150, the count of received decoded bytes to zero (block 712), the count of errored decoded bytes to zero (block 714) and the state to soft decision (e.g., zero (0)) (block 716). Control then proceeds to block 720.

If a new DMT symbol 150 has not started (block 705), control proceeds to block 720 and skips blocks 710, 712, 714 and 716. At block 720, the erasure forecaster sets an index variable to zero (0) to presently consider the first byte of the just decoded codeword (block 720). Using for example, the example mathematical expression illustrated in EQN (1) or the example byte-to-symbol mapper 335 of FIG. 3 and/or 5 to compute the DMT symbol number modulo 2^{M} corresponding to the current codeword (i.e., codeword index) and byte (i.e., index) (block 722). The erasure forecaster then increments the count of bytes decoded for the computed DMT symbol number (block 724) and determines if the presently considered byte of the currently indexed codeword was received errored (block 726).

If the presently considered byte was received in error (e.g., as identified in the actual error location store 315) (block 726), the erasure forecaster increments the count of errored bytes for the computed DMT symbol number (block 728). If the presently considered byte was not received in error (block 726), control proceeds to block 730 while skipping block 728.

At block 730, the erasure forecaster determines if all bytes of the codeword have been processed (block 730). If not all bytes have been processed (block 730), the erasure forecaster increments the byte index so that the next byte of the just decoded codeword is considered (block 732) and control returns to block 722 to process the next byte. If all bytes have been processed (block 730), control proceeds to block 740.

At block 740, the erasure forecaster sets an index into an erasure forecasting state table (e.g., the example state table 325 of FIG. 3 and/or 4) to zero (0) (block 740). Using, for example, the example process of FIG. 8, the erasure forecaster makes a hard decision regarding erasures for the presently considered DMT symbol 150 (block 742). If not all active DMT symbols 150 have been processed (e.g., F<2^{M}−1) (block 744), the erasure forecaster increments the index to consider the next active DMT symbol 150 (block 746) and control returns to block 742 to process the next active DMT symbol 150. If all active DMT symbol 150 have been processed (block 744), control proceeds to block 750.

In the illustrated example of FIG. 7, the erasure forecaster at blocks 740, 742, 744 and/or 746 processes each entry of the erasure forecasting state table. Additionally or alternatively, at blocks 740, 742, 744 and/or 746 the erasure forecaster can only process those DMT symbols 150 having at least one byte in presently considered codeword (i.e., just decoded). For example, at block 722 the erasure forecaster could track and/or record which DMT symbols 150 had at least one byte in the presently considered byte such that only those DMT symbols 150 need be processed at blocks 740, 742, 744 and/or 746. For example, the erasure forecaster could determine the smallest DMT symbol number and the largest DMT symbol number that correspond to the range of DMT symbols 150 having at least one byte in the presently considered codeword. The erasure forecaster could alternatively determine the smallest DMT symbol number of a DMT symbol having at least one byte in the presently considered codeword and the number of DMT symbols having at least one byte in the presently considered codeword.

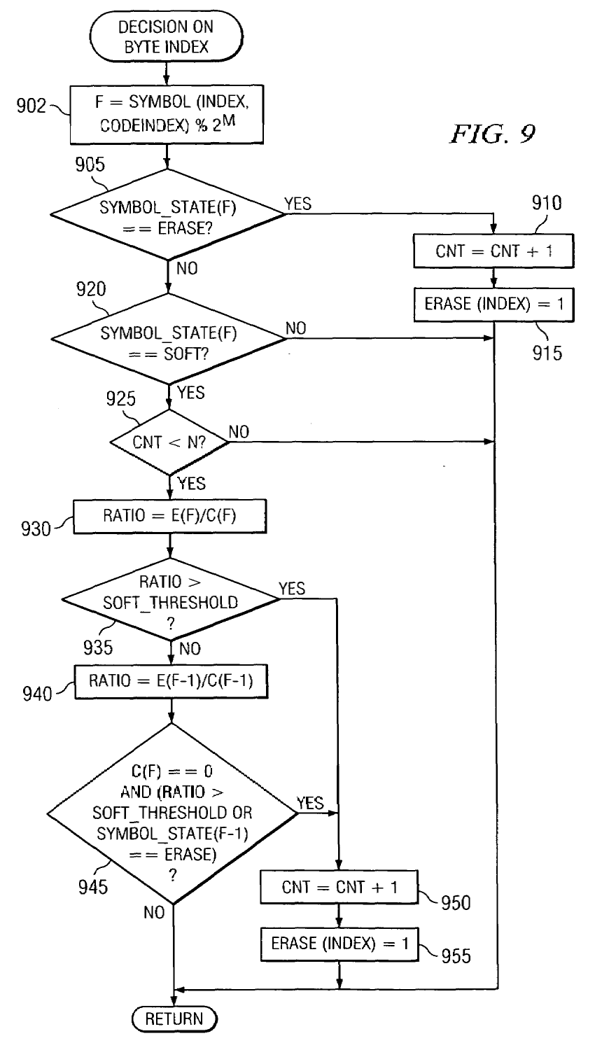

At block 750, the erasure forecaster sets a count of the number of erasures marked for the next codeword to zero (block 750) and sets an index variable to zero (0) to presently consider the first byte of the next codeword (block 752). Using for example, the example process of FIG. 9, the erasure forecaster makes an erasure decision for the presently considered byte of the next codeword (block 754). If not all bytes have been processed (block 756), the erasure forecaster increments the byte index so that the next byte of the next codeword is considered (block 758) and control returns to block 754 to make an erasure decision for the next byte of the next codeword. If all bytes have been processed (block 756), control exits from the example process of FIG. 7.

The example process of FIG. 8 begins, for example, when called from the example process for FIG. 7 to make a hard erasure decision for a DMT symbol 150 F. The erasure forecaster compares the number of already decoded bytes C(F) associated with DMT symbol 150 F with a count threshold C_MAX (block 805). If the count of decoded bytes C(F) equals or exceeds the threshold C_MAX (block 805), the erasure forecaster computes the ratio of the number of errored received bytes to the number of decoded bytes (block 810). If the ratio equals or exceeds a hard decision threshold (block 815), the erasure forecaster sets the erasure state to indicate that all subsequent bytes of DMT symbol 150 F should be erased (block 820). If the ratio does not exceed the threshold (block 815), the erasure forecaster sets the erasure state to indicate that all subsequent bytes of DMT symbol 150 F should not be erased (block 825). At block 815, the erasure forecaster may, additionally or alternatively, check the state of a configuration flag and/or variable that indicates whether the ratio and/or a comparison of the number of errored received bytes should be used to make the hard decision. Control then returns from the example process of FIG. 8 to, for example, the example process of FIG. 7.

If the count of decoded bytes C(F) is less than the threshold C_MAX (block 805), then control returns from the example process of FIG. 8 to, for example, the example process of FIG. 7.

The example process of FIG. 9 begins, for example, when called from the example process for FIG. 7 to make a soft erasure decision for a presently considered byte of the next codeword to be decoded. Using for example, the example expression illustrated in EQN (1) or the example byte-to-symbol mapper 335 of FIG. 3 and/or 5, the erasure forecaster computes the DMT symbol number modulo 2^{M} corresponding to the next codeword to be decoded and the presently considered byte (block 902). If the state of corresponding DMT symbol 150 indicates that a hard decision to erase subsequent bytes of the DMT symbol 150 was previously made (block 905), the count of the number of bytes thus far marked for erasure is incremented (block 910) and the byte is marked for erasure (block 915). Control then returns from the example process for FIG. 9 to, for example, the process of FIG. 7.

If a hard decision to erase the corresponding DMT symbol 150 was not made (block 905), the erasure forecaster checks if the erasure state of the corresponding DMT symbol 150 indicates that soft decisions are being made (block 920). If soft decisions are not being made (i.e., a hard decision not to erase the corresponding DMT symbol 150 was previously made) (block 920), control returns from the example process for FIG. 9 to, for example, the process of FIG. 7.

If soft decisions are currently being made for the corresponding DMT symbol 150 (block 920), the erasure forecaster determines if the number of bytes of the next codeword already marked for erasure is less than the maximum number of erasures supported by the RS decoder 305 (i.e., the number of redundancy bytes) (block 925). If no more bytes can be marked for erasure (block 925), control returns from the example process for FIG. 9 to, for example, the process of FIG. 7.

If at least one more byte can be erased (block 925), the erasure forecaster compares the ratio of the number of errored bytes and the number of already decoded bytes to a soft decision threshold (block 930). If the ratio equals or exceeds a threshold (block 935), the count of the number of bytes thus far marked for erasure is incremented (block 950) and the byte is marked for erasure (block 955). At block 935, the erasure forecaster may, additionally or alternatively, check the state of a configuration flag and/or variable that indicates whether the ratio and/or a comparison of the number of errored received bytes should be used to make the hard decision. Control then returns from the example process for FIG. 9 to, for example, the process of FIG. 7.

If the ratio does not exceed the threshold (block 935), the erasure forecaster computes the ratio of the number of errored bytes and the number of decoded bytes for the previous DMT symbol 150 (block 940). If the number of bytes received for the current DMT symbol 150 is zero (0) and if the prior DMT symbol 150 is erasing due to a soft decision (i.e., the ratio for the previous DMT symbol 150 equals or exceeds the threshold) or a hard decision (block 945), the count of the number of bytes thus far marked for erasure is incremented (block 950) and the byte is marked for erasure (block 955). In this way, if a previous DMT symbol 150 is being erased then a starting decision to erase the next DMT symbol 150 is made. At block 945, the erasure forecaster may, additionally or alternatively, check the state of a configuration flag and/or variable that indicates whether the ratio and/or a comparison of the number of errored received bytes should be used to make the hard decision. Control then returns from the example process for FIG. 9 to, for example, the process of FIG. 7.

FIG. 10 is a schematic diagram of an example processor platform 1000 that may be used and/or programmed to implement the example erasure forecaster 320 and/or, more generally, the example RS decoder sub-system 175 of FIG. 1 and/or 2. For example, the processor platform 1000 can be implemented by one or more general purpose processors, cores, microcontrollers, etc.

The processor platform 1000 of the example of FIG. 10 includes a general purpose programmable processor 1005. The processor 1005 executes coded instructions 1010 and/or 1012 present in main memory of the processor 1005 (e.g., within a RAM 1015 and/or within a ROM 1020). The processor 1005 may be any type of processing unit, such as a processor from the TI® family of DSPs, cores, processors and/or microcontrollers. The processor 1005 may execute, among other things, the example processes of FIGS. 7, 8 and/or 9 to perform erasure forecasting. The processor 1005 is in communication with the main memory (including the ROM 1020 and the RAM 1015) via a bus 1025. The RAM 1015 may be implemented by dynamic RAM (DRAM), Synchronous DRAM (SDRAM), and/or any other type of RAM device, and ROM may be implemented by flash memory and/or any other desired type of memory device. Access to the memory 1015 and 1020 maybe controlled by a memory controller (not shown). The RAM 1015 may be used to store, for example, the actual error locations store 315, the erasure locations store 310, the erasure forecasting state table 325 and/or the control variables 330 of FIG. 3 and/or 4.

The processor platform 1000 also includes an interface circuit 1030. The interface circuit 1030 may be implemented by any type of interface standard, such as an external memory interface, serial port, general purpose input/output, etc. One or more input devices 1035 and one or more output devices 1040 are connected to the interface circuit 1030. The input devices 1035 and/or output devices 1040 may be used to, for example, implement interfaces to, for and/or between any or all of the example RS decoder 305, the example erasure locations store 310, the example actual error locations store 315, the erasure forecaster 320, the example erasure forecasting state table 325, the example control variables 330 and/or the example byte-to-symbol mapper 335.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

1. A method comprising:
analyzing a first decoding error associated with first interleaved data during a first time interval; and
analyzing a second decoding error associated with second interleaved data during a second time interval, wherein the second time interval at least begins before making a first decision whether to erase a first element associated with the first interleaved data.

2. A method as defined in claim 1, wherein the first element associated with the first interleaved data is at least one of a word, a byte or a bit.

3. A method as defined in claim 1, wherein analyzing the first decoding error and the second decoding error are performed independently.

4. A method as defined in claim 1, further comprising making a second decision whether to erase a second element associated with the first interleaved data prior to a beginning of the second time interval.

5. (canceled)

6. A method as defined in claim 1, wherein analyzing the first decoding error associated with the first interleaved data comprises:
decoding a first codeword associated with the first interleaved data;
receiving a first error indication for a second element of the first codeword; and
deciding whether to erase the first element based on the first error indication, the first element associated with a second codeword.

7. (canceled)

8. (canceled)

9. A method as defined in claim 6, wherein deciding whether to erase the first element based on the first error indication comprises:
determining a count of decoded codeword elements associated with the first interleaved data;
adding the first error indication to a count of errors;
determining a ratio of the count of errors and the count; and
erasing the first element if the ratio exceeds a threshold.

10. (canceled)

11. A method as defined in claim 6, further comprising:
de-interleaving data received in at least the first and second interleaved data to obtain the first and the second codewords; and
decoding the second codeword based upon the erasure decision for the first element.

12-21. (canceled)

22. An apparatus comprising:
a forward error correction (FEC) decoder to decode a first codeword and to provide a first error indication for the first codeword;
an erasure forecaster to make an erasure decision for a second codeword based on the first error indication; and
an erasure forecasting state table including a first field associated with first interleaved data and a second field associated with second interleaved data, the second codeword containing a first element from the first interleaved data and a second element from the second interleaved data.

23. An apparatus as defined in claim 22, wherein forward error correction (FEC) decoder is a Reed-Solomon (RS) decoder supporting erasure decoding.

24. An apparatus as defined in claim 22, wherein the element of the first interleaved data is at least one of a word, a byte or a bit.

25. An apparatus as defined in claim 22, further comprising a byte-to-symbol mapper to determine which of the first and the second interleaved data is associated with a third element of the second codeword.

26. An apparatus as defined in claim 22, wherein the first field contains at least one of a count of decoded elements, a count of the errored elements, an erasure decision state or a frame number.

27. An apparatus as defined in claim 22, wherein the first field contains a count of decoded elements and the erasure forecasting state table further includes a third field that contains a count of errored elements associated with the first interleaved data, and a fourth field that contains an erasure decision state associated with the first interleaved data.

28. (canceled)

29. (canceled)

30. An apparatus as defined in claim 22, further comprising:
a receiver to process a received DMT symbol to extract an interleaved codeword; and
a de-interleaver to de-interleaver the interleaved codeword to form the first and the second codewords.

31. An article of manufacture storing machine accessible instructions which, when executed, cause a machine to:
decide during a first time interval whether to erase a first element of a first codeword, the first element received in a first data frame;
decide during the first time interval whether to erase a second element of the first codeword, the second element received in a second frame; and
decode the first codeword during a second time interval using the erasure decisions for the first and second elements, the second time interval occurring after the first time interval.

32. An article of manufacture as defined in claim 31, wherein the machine accessible instructions, when executed, cause the machine to:
decode a second codeword during a third time interval that precedes the first time interval; and
determine during the first time interval whether an error occurs in a third element of the second codeword, the third element received in the second frame, and wherein deciding whether to erase the second element is based upon the determined error of the third element.

33. An article of manufacture as defined in claim 31, wherein the machine accessible instructions, when executed, cause the machine to decide during the first time interval whether to erase the first element of the first codeword by:
determining if an error occurs in a fourth element of a second codeword, the fourth element received in the first frame; and
deciding whether to erase the first element based upon the determined error of the fourth element.

34. An article of manufacture as defined in claim 31, wherein the machine accessible instructions, when executed, cause the machine to decide during the first time interval whether to erase the first element of the first codeword by making a final decision during a third time interval to erase all elements associated with the first frame, the third time interval preceding the first time interval.

35. An article of manufacture as defined in claim 31, wherein the machine accessible instructions, when executed, cause the machine to decode the second codeword based upon the determined erasures of the second elements of the first and the second frames.

36. An article of manufacture as defined in claim 31, wherein the machine accessible instructions, when executed, cause the machine to decide during the first time interval whether to erase the first element of the first codeword by:
determining if the first frame is corrupted; and
erasing the first element if the first frame is corrupted.

37. (canceled)
